(19) United States
(12) Patent Application Publication
(10) Pub. No.: US 2026/0330075 A1
(43) Pub. Date: Oct. 22, 2026

(54) MODELING SYSTEM, DATA GENERATION APPARATUS, AND DATA GENERATION METHOD

(71) Applicant: MIMAKI ENGINEERING CO., LTD., Nagano (JP)

(72) Inventor: Kenji Harayama, Nagano (JP)

(73) Assignee: MIMAKI ENGINEERING CO., LTD., Nagano (JP)

(21) Appl. No.: 19/574,427

(22) Filed: Mar. 22, 2026

(30) Foreign Application Priority Data
Apr. 16, 2025 (JP) 2025-067579

(51) Int. Cl. G06F 30/12

(52) U.S. Cl. CPC G06F 30/12

(57) ABSTRACT

Provided is a modeling system having a data processing unit 12 that is a data generation unit for generating molded object specification data indicating a shape of a molded object; and a modeling execution unit for executing modeling of the molded object using the molded object specification data. The data processing unit generates the molded object specification data by performing: an input process for inputting data indicating a three-dimensional shape in which at least a part of a surface is colored; a color range detection process for detecting a range in which color is applied in the input data; and a data generation process for generating the molded object specification data. In the data generation process, at least a part of a surface of the three-dimensional shape becomes a shape of the molded object, and at least a boundary part of the detected color range becomes a preset shape.

### CROSS-REFERENCE TO RELATED APPLICATION

This application claims the priority benefit of Japanese application serial no. 2025-067579, filed on Apr. 16, 2025. The entirety of the above-mentioned patent application is hereby incorporated by reference herein and made a part of this specification.

### BACKGROUND

### Technical Field

The present invention relates to a modeling system, a data generation apparatus, and a data generation method.

### Description of Related Art

In recent years, modeling apparatuses that model three-dimensional molded objects have been widely used (see, for example, Patent Document 1, Japanese Patent Application Laid-Open Publication No. 2015-071282). As modeling apparatuses, apparatuses that perform modeling by various methods such as the FDM method, the stereolithography, and the inkjet method have been used.

When modeling a molded object with a modeling apparatus, coloring may be performed on the molded object in a subsequent process after the modeling by the modeling apparatus is completed. In this case, for example, after modeling a molded object with a single-color material (modeling material) such as white in the modeling apparatus, coloring is performed on the molded object by manual work by an operator or the like. In this case, coloring with multiple colors may be performed on the molded object by varying the color for each region. For example, when coloring a molded object representing a character from a manga or animation, it is conceivable to perform coloring using about several colors (for example, about 3 to 5 colors). In this case, an operator who performs coloring on the molded object performs the coloring work by, for example, painting different colors according to a sample while looking at a colored sample.

However, in this case, depending on the shape of the molded object or the like, it may be difficult to determine the boundary part of the region where colors are to be painted differently even when checking the sample. More specifically, for example, when coloring is performed on one surface of a molded object such that the color differs at the center (center-parted coloring), it may be difficult to determine the center position. In this case, for example, if measurement or the like is performed to determine where the center is, the work process increases, and the efficiency of the work is significantly reduced. Thus, it is desired that coloring on a molded object after modeling be performed more easily and appropriately. Accordingly, the present invention provides a modeling system, a data generation apparatus, and a data generation method.

### SUMMARY

The inventor of the present application considered adding (imparting) a predetermined shape to a boundary part where a plurality of regions to be colored with mutually different colors contact each other, regarding a case where coloring is performed on a molded object after modeling. With this configuration, for example, regions to be colored on the molded object may be easily and appropriately identified. Furthermore, the inventor of the present application considered detecting the boundary part of the region to be colored by using data with colors applied to the surface as input data indicating the shape of the molded object and deforming the shape at a position corresponding to the boundary part in the input data based on the detection result. With this configuration, for example, data with a predetermined shape imparted to the boundary part of the region to be colored may be easily and appropriately generated. By performing modeling based on this data, for example, coloring on the molded object after modeling may be easily and appropriately performed.

Further, the inventor of the present application discovered the features necessary to obtain such effects through further diligent research, and arrived at the present invention. The present invention is a modeling system for modeling a three-dimensional molded object, and the modeling system includes: a data generation unit, configured to generate molded object specification data, which is data indicating a shape of the molded object, a modeling execution unit, configured to execute modeling of the molded object based on the molded object specification data. The data generation unit performs an input process of inputting, as input data, data indicating a three-dimensional shape in which at least a part of a surface is colored, a color range detection process for detecting a color range that is a range in which the color is applied in the input data, and a data generation process of generating the molded object specification data in which a shape obtained by changing at least a part of a shape of a surface in the three-dimensional shape indicated by the input data becomes a shape of the molded object and generating the molded object specification data in which at least a boundary part in the color range detected in the color range detection process becomes a preset shape.

With this configuration, for example, a molded object in which the boundary part of the region to be colored is easily identified may be appropriately modeled. Further, this allows, for example, even when modeling a molded object with a single-color material (modeling material), coloring of the molded object after modeling may be performed more easily and appropriately. Further, in this case, in the data generation process, the data generation unit generates, for example, the molded object specification data indicating a shape in which a convex portion or a concave portion along the boundary part is added to the three-dimensional shape indicated by the input data. With this configuration, for example, the boundary part of the region to be colored in the molded object may be easily and appropriately identified. More specifically, in this case, the data generation unit adds, to the three-dimensional shape indicated by the input data, as a convex portion or concave portion at the boundary part, for example, a convex portion or concave portion that continuously extends along the boundary part. Further, the data generation unit may add, to the three-dimensional shape indicated by the input data, as a convex portion or concave portion at the boundary part, convex portions or concave portions that are intermittently aligned along the boundary part. The convex portions or concave portions that are intermittently aligned along the boundary part may be considered, for example, as an arrangement of a plurality of convex portions or concave portions aligned along the boundary part with gaps therebetween.

Further, as a shape to be added to the boundary part, for example, a shape other than a convex portion or concave portion along the boundary part may be used. In this case, for example, it is conceivable to form a textured shape having a plurality of convex portions and a plurality of concave portions on a predetermined range of the surface of the molded object. More specifically, in this case, in the data generation process, the data generation unit generates, for example, molded object specification data indicating a shape in which textured unevenness is added to at least a part of the range along the boundary part with respect to the three-dimensional shape indicated by the input data. Even with this configuration, for example, a molded object in which the boundary part of the region to be colored is easily identified may be appropriately modeled.

Further, regarding the shape to be added to the boundary part, for example, it is conceivable to vary the surface state of the molded object depending on the color to be applied. In this case, the boundary part may be considered to have a preset shape by, for example, becoming a boundary between regions having mutually different surface states. In this case, in the input process, the data generation unit inputs, for example, input data in which a first color is applied to a first region on the surface and a second color different from the first color is applied to a second region on a surface different from the first region. Then, in the color range detection process, the data generation unit detects, for example, a first range that is a color range to which the first color is applied and a second range that is a color range to which the second color is applied. Further, in the data generation process, the data generation unit generates, for example, molded object specification data in which, with respect to the three-dimensional shape indicated by the input data, a surface state in the first range is set to a first state and a surface state in the second range is set to a second state different from the first state. Even with this configuration, for example, a molded object in which the boundary part of the region to be colored has a preset shape may be appropriately modeled. Further, this allows, for example, a molded object in which the boundary part of the region to be colored is easily identified to be appropriately modeled. Further, in this case, regarding the surface state of each region such as the first and second regions, for example, it is conceivable to apply mutually different textured patterns. Further, in this case, it is also conceivable to add the same textured pattern to the entire region for each region.

Further, regarding the process executed by the data generation unit, more specifically, in the data generation process, the data generation unit performs, for example, a deformed shape data generation process that generates deformed shape data, which is data indicating a shape in which a part of the three-dimensional shape indicated by the input data is changed, and a slice data generation process that generates slice data, which is data indicating a cross-section of the molded object, based on the deformed shape data. In this case, in the deformed shape data generation process, the data generation unit changes, for example, a part of the three-dimensional shape indicated by the input data so that at least the boundary part in the color range has a preset shape based on the color range detected in the color range detection process. Further, in this case, the modeling execution unit models the molded object by, for example, stacking modeling material based on the slice data. With this configuration, for example, a molded object in which the boundary part of the region to be colored is easily identified may be appropriately modeled.

Further, as a configuration of the present invention, for example, a configuration of a data generation apparatus or a data generation method having the same features as described above may also be considered. In this case, the data generation apparatus may be considered as, for example, an apparatus that executes input process, color range detection process, data generation process, and the like. Further, the data generation method may be considered as, for example, a method including an input stage, a color range detection stage, a data generation stage, and the like, which are stages corresponding to the input process, the color range detection process, the data generation process, and the like. In these cases as well, for example, the same effects as described above may be obtained.

### BRIEF DESCRIPTION OF THE DRAWINGS

FIGS. 1A and 1B are diagrams for describing a modeling system 10 according to one embodiment of the present invention.

FIG. 1A shows an example of a configuration of the modeling system 10. FIG. 1B shows an example of a configuration of a molded object 50 modeled in the modeling system 10.

FIGS. 2A and 2B are diagrams for describing in more detail an operation of generating molded object specification data in the data processing unit 12. FIG. 2A shows in a simplified manner a relationship between color 3D data 40 used as input data in the data processing unit 12 and a shape of a molded object 50 modeled in the modeling execution unit 14. FIG. 2B shows a specific example of a shape of a boundary part 154 in the molded object 50.

FIGS. 3A and 3B are diagrams for describing in more detail an operation of generating molded object specification data in the data processing unit 12. FIG. 3A is a flowchart showing an example of an operation of generating molded object specification data in the data processing unit 12. FIG. 3B shows an example of a functional configuration of the data processing unit 12.

FIGS. 4A, 4B, and 4C are diagrams for describing modification examples of a shape to be added to boundary parts 154 of a plurality of regions 152 in the molded object 50. FIG. 4A shows a modification example of a shape to be added to the boundary part 154. FIG. 4B shows a further modification example of a shape to be added to the boundary part 154. FIG. 4C shows an example of a state near the boundary part 154 in a further modification example of an operation of the data processing unit 12.

### DESCRIPTION OF THE EMBODIMENTS

According to the present invention, for example, coloring of the molded object after modeling may be performed more easily and appropriately.

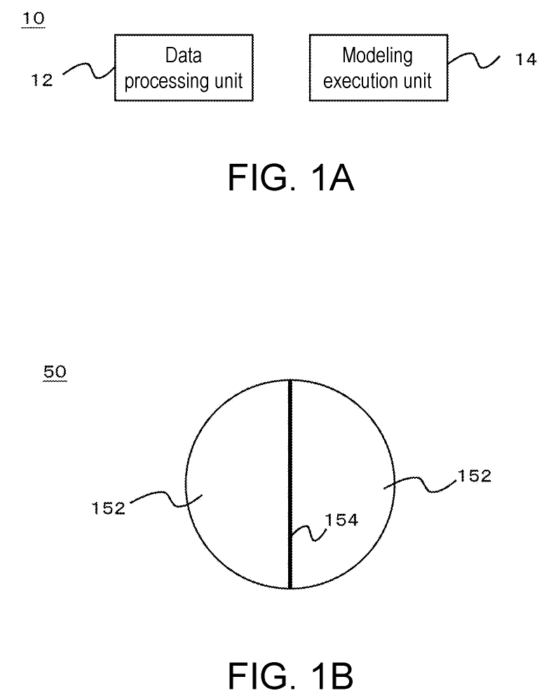

Hereinafter, embodiments according to the present invention will be described with reference to the drawings. FIGS. 1A and 1B is a diagram for describing a modeling system 10 according to one embodiment of the present invention. FIG. 1A shows an example of a configuration of the modeling system 10. FIG. 1B shows an example of a configuration of a molded object 50 modeled in the modeling system 10. Except for the points described below, the modeling system 10 and each part of the modeling system 10 of this example may have the same or similar features as a known modeling system and each part thereof. In this example, the modeling system 10 is a system that models a three-dimensional molded object and includes a data processing unit 12 and a modeling execution unit 14.

The data processing unit 12 is an example of a data generation unit and generates molded object specification data that is data indicating a shape of the molded object 50 in a predetermined format. Further, in this example, the data processing unit 12 supplies the generated molded object specification data to the modeling execution unit 14, thereby causing the modeling execution unit 14 to execute a modeling operation. In this case, the molded object specification data may be considered as, for example, data for controlling an operation of the modeling execution unit 14 in a format adapted to an operation method of modeling executed in the modeling execution unit 14. More specifically, in this example, the data processing unit 12 uses color 3D data, which is data indicating a three-dimensional shape in which at least a part of a surface is colored, as input data, and based on this input data, generates molded object specification data for causing the modeling execution unit 14 to perform modeling in a single color. In this case, the data processing unit 12 generates, as the molded object specification data, slice data indicating shapes of cross sections of the molded object 50 at a plurality of positions in a predetermined stacking direction. The data processing unit 12 may also be considered as, for example, an example of a data generation apparatus that executes a predetermined data generation method. An operation of generating molded object specification data in the data processing unit 12 will be described in more detail later.

Further, the modeling execution unit 14 is a configuration that executes a modeling operation (3D printing) and executes a modeling operation to model the molded object 50 based on the molded object specification data received from the data processing unit 12. Further, by this, the modeling execution unit 14 models the molded object 50 having a shape indicated by the molded object specification data. In this case, the modeling execution unit 14 executes the modeling operation by a known method such as the FDM method. The modeling method executed in the modeling execution unit 14 may be a method other than the FDM method. For example, the modeling method executed in the modeling execution unit 14 may be a method such as stereolithography or inkjet method. Further, as described above, in this example, the data processing unit 12 generates slice data indicating a shape of a cross section of the molded object 50 as the molded object specification data. In this case, the modeling execution unit 14 models the molded object 50 by an additive manufacturing method, for example, by stacking modeling material based on the slice data. With this configuration, for example, the molded object 50 may be appropriately modeled in the modeling system 10.

Further, in this example, the modeling execution unit 14 models a single-color molded object 50 using a single-color (one color) modeling material. In this case, using a single-color modeling material may be considered as, for example, using a material of a predetermined color that is treated as the same type of material. Regarding the single-color molded object 50, it may also be considered that, for example, at least a surface portion of the molded object 50 is single-colored. Further, in this example, the molded object 50 modeled by the modeling execution unit 14 is a molded object 50 that is colored in a separate process performed after completion of modeling in the modeling execution unit 14, and as shown in FIG. 1B, for example, the surface is divided into a plurality of regions 152 by boundary parts 154 of a predetermined shape. In this case, the regions 152 may be considered as, for example, portions that are colored with the same color in a subsequent process. The boundary parts 154 may be considered as, for example, portions that become color boundaries after coloring. Further, the boundary parts 154 may also be considered as, for example, portions that become boundaries for color separation. Regarding the boundary parts 154 having a predetermined shape, it may be considered that, for example, a predetermined shape indicating the boundary parts 154 is formed on the surface of the molded object 50.

By using such boundary parts 154, for example, when executing a process of coloring the molded object 50, it is possible to easily and appropriately grasp the boundaries of a plurality of regions 152 to be colored with mutually different colors. Further, by this, for example, coloring of the molded object 50 may be appropriately performed with high accuracy. Further, in this case, high-quality coloring may be more appropriately performed even when, for example, a worker unfamiliar with the work performs the coloring work.

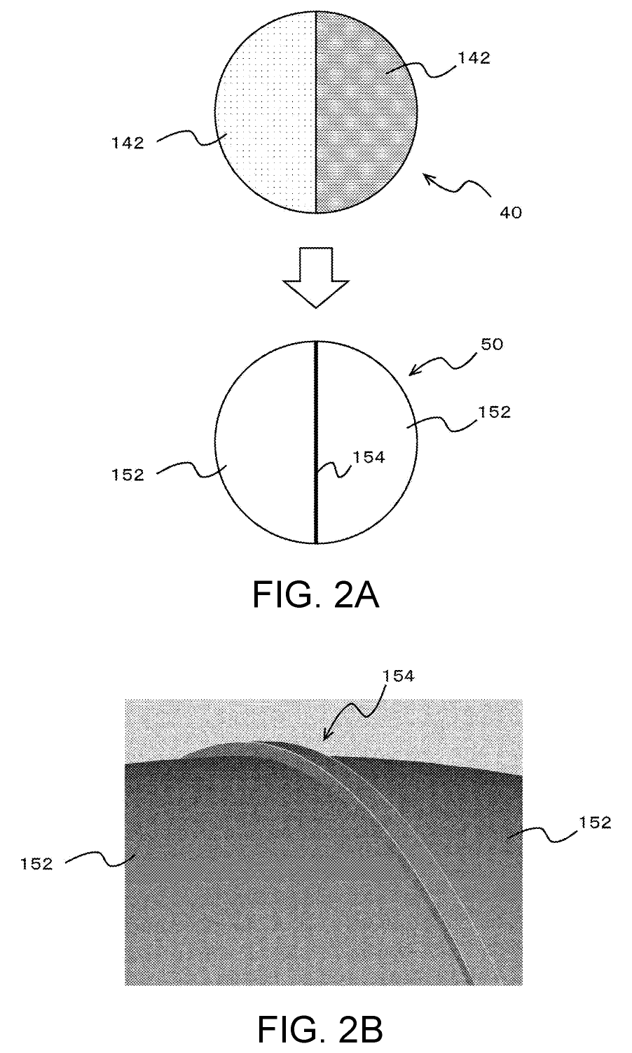

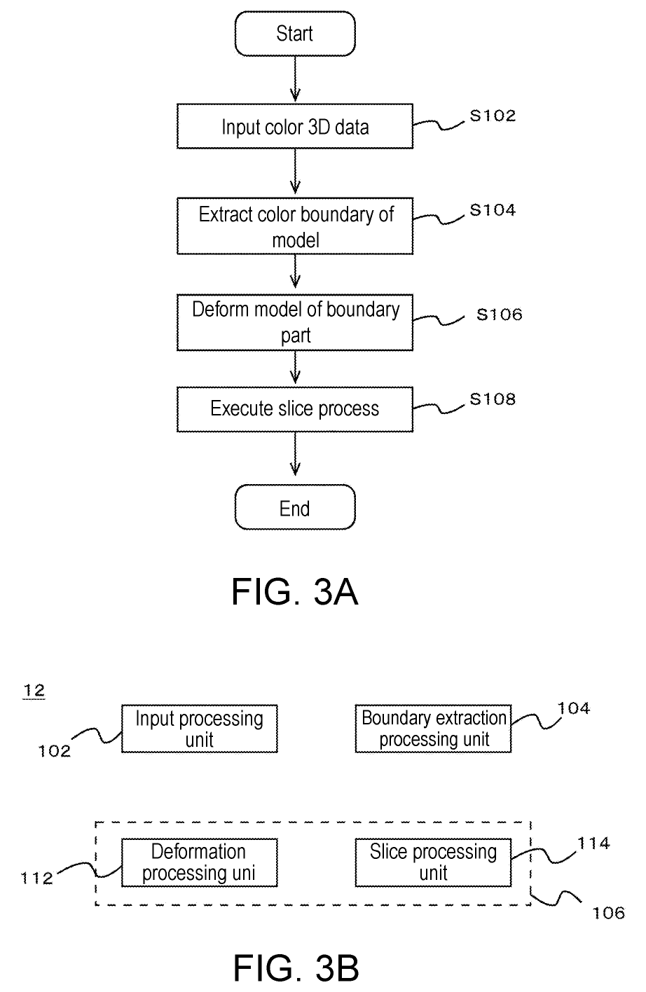

Next, the operation of generating molded object specification data in the data processing unit 12 will be described in more detail. FIGS. 2A, 2B, 3A, and 3B are diagrams for describing in more detail the operation of generating molded object specification data in the data processing unit 12. FIG. 2A shows in a simplified manner a relationship between color 3D data 40 used as input data in the data processing unit 12 and a shape of a molded object 50 modeled in the modeling execution unit 14. FIG. 2B shows a specific example of a shape of a boundary part 154 in the molded object 50.

As described above, in this example, the data processing unit 12 uses the color 3D data 40 as input data for generating the molded object specification data. In this case, the color 3D data 40 may be considered as, for example, data showing a three-dimensional shape having a coloring portion 142 colored with a specified color, as shown in the upper side of FIG. 2A. Further, in FIG. 2A, for convenience of illustration, the coloring portions 142 colored with mutually different colors are illustrated with different hatched patterns. The color 3D data 40 may also be considered as, for example, data in which at least a part of the surface is colored. As the color 3D data 40, for example, 3D format data (three-dimensional data) showing shape and color in a known format may be suitably used. Further, when focusing on how the coloring portion 142 in the color 3D data 40 is colored, the color 3D data 40 may be considered as showing, for example, the molded object 50 in a state where coloring has been performed after modeling in the modeling execution unit 14. Thus, the color 3D data 40 may also be considered as, for example, data showing a three-dimensional shape that serves as a sample for coloring the molded object 50.

Further, as described above, in this example, the modeling execution unit 14 models a single-color molded object 50. In this case, the data processing unit 12 generates molded object specification data showing the single-color molded object 50 based on the color 3D data 40 in which colors are specified for the coloring portion 142. Further, in this example, as the color 3D data 40, data in which a shape corresponding to the boundary part 154 of the region 152 in the molded object 50 is not specified is used. In this case, the data processing unit 12 specifies a shape corresponding to the boundary part 154 of the region 152 in the molded object 50 in the molded object specification data, based on the range of the coloring portion 142 that is colored in the color 3D data 40. More specifically, in this case, the data processing unit 12 detects, for example, the boundary of the coloring portions 142 that are colored with mutually different colors in the color 3D data 40. Then, the data processing unit 12, for example, based on this detection result, deforms the shape of the part corresponding to this boundary in the molded object 50 among the three-dimensional shape shown by the color 3D data 40. Further, thereby, the data processing unit 12 adds (imparts) a predetermined shape to the boundary part 154 of the region 152 in the molded object 50, which is a position corresponding to the boundary of the coloring portion 142 in the color 3D data 40, as shown in FIG. 2A, for example. In this case, the data processing unit 12 generates, for example, the molded object specification data by changing the three-dimensional shape shown by the color 3D data 40 so that the position of the boundary part 154 becomes convex, as shown in FIG. 2B. With this configuration, for example, a preset shape may be appropriately formed for the boundary part 154 of the regions 152 to be colored with mutually different colors in subsequent processes. Further, thereby, for example, the molded object 50 in which the boundary part 154 is easily identified may be appropriately modeled.

In this case, the data processing unit 12 generates the molded object specification data based on the color 3D data 40, for example, by the operation shown in FIG. 3A. FIG. 3A is a flowchart showing an example of an operation of generating molded object specification data in the data processing unit 12. As described above, in the operation of generating the molded object specification data in this example, the data processing unit 12 inputs the color 3D data 40 as input data (S102). In this example, the operation of step S102 is an example of the input process and the operation of the input stage. Further, as the color 3D data 40, for example, as described above, data is used in which the plurality of coloring portions 142 are colored with mutually different colors, and in which the shape corresponding to the boundary part 154 of the region 152 in the molded object 50 is not specified. In this case, the fact that the shape corresponding to the boundary part 154 of the region 152 in the molded object 50 is not specified may be considered as, for example, the shape to be added in subsequent processing to the three-dimensional shape indicated by the color 3D data 40 not being specified. Further, regarding the color 3D data 40, the fact that the shape corresponding to the boundary part 154 of the region 152 in the molded object 50 is not specified may also be considered as, for example, the shape of the portion corresponding to the boundary part 154 in the three-dimensional shape indicated by the color 3D data 40 being different from the shape of the boundary part 154 in the molded object 50 that is actually modeled. Further, as the color applied to the coloring portion 142 in the color 3D data 40, for example, it is conceivable to use the color applied to the molded object 50 in the coloring process after the modeling of the molded object 50. In this case, the color applied to the molded object 50 in the coloring process after the modeling of the molded object 50 may be considered as, for example, the color applied to the region 152 in the molded object 50 corresponding to the coloring portion 142 in the color 3D data 40.

Further, as described below, in this example, the color applied to the coloring portion 142 of the color 3D data 40 is used to determine the position of the boundary part 154 in the molded object 50. In this case, regarding the color 3D data 40 used in this example, it may be considered as, for example, input data, and the like in which a first color is applied to the coloring portion 142 that serves as a first region on the surface of the three-dimensional shape indicated by the color 3D data 40, and a second color different from the first color is applied to the coloring portion 142 that serves as a second region different from the first region on the surface. By using such color 3D data 40, for example, the position of the boundary part 154 in the molded object 50 may be appropriately determined. Further, it is also conceivable to use, as the color applied to the coloring portion 142 in the color 3D data 40, for example, a color different from the color applied to the molded object 50 in the coloring process. In this case as well, for example, by using the color 3D data 40 in which the colors of the coloring portions 142 corresponding to mutually different regions 152 in the molded object 50 are made different from each other, the position of the boundary part 154 in the molded object 50 may be appropriately determined.

Further, following the operation of step S102, the data processing unit 12 detects a color range, which is a range where color is applied in the color 3D data 40, and extracts a color boundary, which is a boundary of colors in the color 3D data 40, based on the color range (S104). In this example, the operation of step S104 is an example of the operation of the color range detection process and the color range detection stage. The color range may be considered as, for example, the range of the coloring portion 142 where the same color is applied in the color 3D data 40. The color boundary may be considered as, for example, a boundary of color ranges corresponding to mutually different colors. Further, in consideration of the relationship with the operation described below, in this example, the color boundary may be considered as, for example, a part corresponding to the boundary part 154 of the region 152 in the molded object 50. Further, in consideration of the relationship with the first color and the second color described above, the operation of the data processing unit 12 in step S104 may be considered as, for example, an operation of detecting a first range, which is a color range where the first color is applied, and a second range, which is a color range where the second color is applied. According to this example, for example, the color boundary corresponding to the boundary part 154 of the region 152 in the molded object 50 may be appropriately extracted.

Further, following the operation of step S104, the data processing unit 12 generates deformed shape data by performing deformation of a model that deforms the color boundary part in the three-dimensional shape indicated by the color 3D data 40 (S106). In this example, the operation of step S106 is an example of the operation of the deformed shape data generation process and the deformed shape data generation stage. The deformed shape data may be considered as, for example, data indicating a shape in which a part of the three-dimensional shape indicated by the color 3D data 40 is changed. Further, more specifically, in this example, the data processing unit 12 changes a part of the three-dimensional shape indicated by the color 3D data 40 so that the position corresponding to the color boundary on the surface of the three-dimensional shape becomes a convex portion and generates the deformed shape data. In this case, regarding the operation of the data processing unit 12 in step S106, it may be considered as, for example, changing a part of the three-dimensional shape indicated by the color 3D data 40 based on the color range detected in step S104 so that at least the boundary part in the color range becomes a preset shape. Further, following the operation of step S106, the data processing unit 12 generates slice data indicating a cross-section of the molded object 50 to be molded by the modeling execution unit 14 based on the deformed shape data (S108). In this example, the operation of step S108 is an example of the operation of the slice data generation process and the slice data generation stage. In step S108, the data processing unit 12 generates slice data indicating the shape of the cross-section at each position in the stacking direction as molded object specification data by, for example, calculating the cross-sectional shape at each position at preset intervals in a predetermined stacking direction for the shape indicated by the deformed shape data.

Further, in this example, the operations of step S106 and step S108 are also an example of the operations of the data generation process and the data generation stage. The data generation process and the data generation stage may be considered as, for example, a process and a stage for generating molded object specification data in which a shape obtained by changing the shape of at least a part of the surface in the three-dimensional shape indicated by the color 3D data 40 becomes the shape of the molded object 50. The operations performed by the data processing unit 12 in step S106 and step S108 may also be considered as, for example, a process for generating molded object specification data in which at least the boundary part in the color range detected in step S104 becomes a preset shape. Further, more specifically, in this example, as described above, the data processing unit 12 generates molded object specification data indicating a shape in which a convex portion along the boundary part 154 is added to the three-dimensional shape indicated by the color 3D data 40.

Further, in this example, the data processing unit 12 supplies the generated molded object specification data (slice data) to the modeling execution unit 14, thereby causing the modeling execution unit 14 to model the molded object 50 having the shape indicated by the molded object specification data. In this case, the operation of modeling the molded object in the modeling execution unit 14 may be considered as, for example, an example of the operations of a modeling process and a modeling stage. Further, as can be understood from the above description, in this example, the modeling execution unit 14 models the molded object 50 in which the boundary part 154 of the plurality of regions 152 becomes a convex portion, based on the molded object specification data. According to this example, for example, the molded object 50 in which the boundary part 154 of the region 152 to be colored is easily and appropriately identified may be appropriately modeled.

Further, regarding the operation of the data processing unit 12 described above, when considering the functional configuration of the data processing unit 12, the data processing unit 12 may be considered to have, for example, the configuration shown in FIG. 3B. FIG. 3B shows an example of a functional configuration of the data processing unit 12. In the illustrated configuration, the data processing unit 12 functionally includes an input processing unit 102, a boundary extraction processing unit 104, and a data generation processing unit 106. Further, the data generation processing unit 106 includes a deformation processing unit 112 and a slice processing unit 114. In this case, the data processing unit 12 functionally having these configurations may be considered as, for example, at least a part of the data processing unit 12 functioning as each of these configurations when executing the flowchart shown in FIG. 3A. In this case, at least a part of the data processing unit 12 functions as each of these configurations according to a program such as firmware.

Further, more specifically, in this case, the input processing unit 102 is a functional configuration corresponding to the operation of step S102. The input processing unit 102 inputs the color 3D data 40 to the data processing unit 12 by, for example, receiving a user's instruction and reading the color 3D data 40 based on this instruction. Further, the boundary extraction processing unit 104 is a functional configuration corresponding to the operation of step S104. In this example, the boundary extraction processing unit 104 is an example of a color range detection unit and extracts the color boundary in the color 3D data 40 by detecting the color range in the color 3D data 40. The data generation processing unit 106 is a functional configuration corresponding to the operations of step S106 and step S108. Further, in the data generation processing unit 106, the deformation processing unit 112 is a functional configuration corresponding to the operation of step S106. In this example, the deformation processing unit 112 is an example of a deformed shape data generation unit and generates deformed shape data by deforming the color boundary part in the three-dimensional shape indicated by the color 3D data 40. Further, the slice processing unit 114 is a functional configuration corresponding to the operation of step S108 and generates slice data based on the deformed shape data. According to this example, for example, the data processing unit 12 may appropriately generate molded object specification data based on the color 3D data 40.

Subsequently, the shape and the like formed at the position of the boundary part 154 of the region 152 in the molded object 50 will be described in more detail. As described above, in this example, the data processing unit 12 deforms the three-dimensional shape indicated by the color 3D data 40 so that the boundary parts 154 of the plurality of regions 152 in the molded object 50 become convex portions and generates molded object specification data. In this case, as also described above, for example, a molded object 50 may be appropriately modeled in which the boundary parts 154 of the regions 152 to be colored in the subsequent coloring process may be easily identified. Further, by this, for example, coloring of the molded object 50 after modeling may be performed more easily and appropriately. Further, in this case, for example, by forming convex portions at the boundary parts 154 of the regions 152 in the molded object 50, it is possible to make it less likely that color extends outside the region during execution of the process of coloring the molded object 50. Further, by this, for example, even in cases where the skill of the worker performing the coloring is low, coloring of the molded object 50 may be performed more appropriately.

Further, in this case, the data processing unit 12 adds, for example, a convex portion that continuously extends along the boundary part 154 to the three-dimensional shape indicated by the color 3D data 40. The convex portion that continuously extends along the boundary part 154 may be considered, for example, as a convex portion that is connected along the boundary part 154 over the entire boundary part 154. With this configuration, for example, the boundary parts 154 of the plurality of regions 152 in the molded object 50 may be identified more easily and appropriately. Further, the data processing unit 12 may add, for example, convex portions that are intermittently aligned along the boundary part 154 to the three-dimensional shape indicated by the color 3D data 40. The convex portions that are intermittently aligned along the boundary part 154 may be considered, for example, as an arrangement of a plurality of convex portions that are aligned along the boundary part 154 with gaps in between. Even with this configuration, for example, the boundary parts 154 of the plurality of regions 152 in the molded object 50 may be easily and appropriately identified.

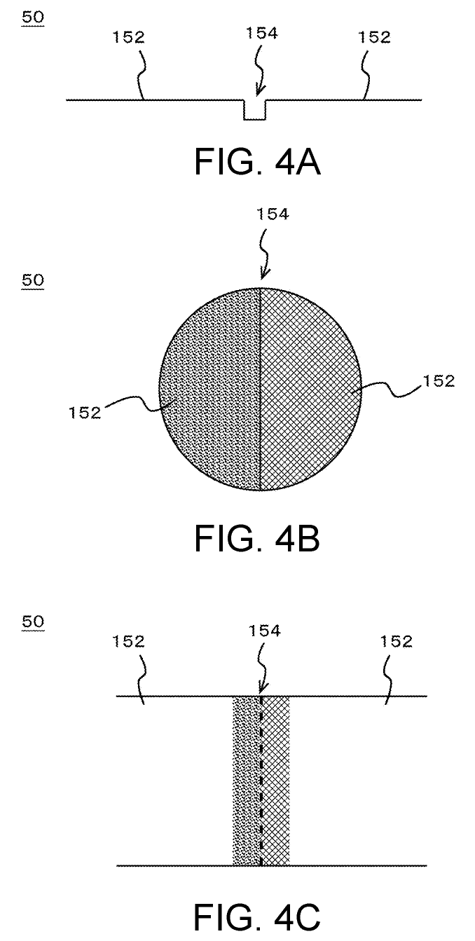

Further, in a modification example of the operation of the data processing unit 12, the shape of the boundary part 154 may be a shape other than a convex portion, for example, as shown in FIGS. 4A, 4B, and 4C. FIGS. 4A, 4B, and 4C are diagrams describing modification examples of a shape to be added to the boundary parts 154 of the plurality of regions 152 in the molded object 50. FIG. 4A shows a modification example of a shape to be added to the boundary part 154. Except for the points described below, in FIG. 4, configurations with the same reference numerals as in FIGS. 1A to 3B may have the same or similar features as the configurations in FIGS. 1A to 3B. Further, in the modification example shown in FIG. 4A, the data processing unit 12 changes the three-dimensional shape indicated by the color 3D data 40 so that a concave portion is added to the boundary part 154 instead of the convex portion described above and generates the molded object specification data. In this case, adding a concave portion to the boundary part 154 may be considered, for example, as generating molded object specification data indicating a shape in which a concave portion that did not exist in the three-dimensional shape indicated by the color 3D data 40 has been added. Even with this configuration, for example, the boundary parts 154 of the plurality of regions 152 in the molded object 50 may be easily and appropriately identified. As such a concave portion, for example, a concave portion that continuously extends along the boundary part 154 may be suitably used. Further, as the concave portion, for example, concave portions that are intermittently aligned along the boundary part 154 may be used.

Further, as the shape to be added to the boundary part 154 of the region 152 in the molded object 50, for example, a shape other than a convex portion or a concave portion along the boundary part 154 may be used. In this case, for example, as shown in FIG. 4B, it is conceivable to add a predetermined uneven pattern or the like to the surface of the region 152 in the molded object 50 and vary the pattern for each region 152. FIG. 4B shows a further modification example of a shape to be added to the boundary part 154. For convenience of illustration, in FIG. 4B, the differences in the surface states due to the regions 152 are illustrated with different hatched patterns. In this case, the pattern on the surface of the region 152 may be considered, for example, as a pattern according to the size of the unevenness formed on the surface and the arrangement of the unevenness. Then, varying the pattern for each region 152 may be considered, for example, as corresponding to varying the surface state of the molded object 50 according to the color to be applied after modeling. Further, the boundary parts 154 of the plurality of regions 152 may be considered, for example, as becoming boundaries of mutually different patterns. In this case, the boundary part 154 may be considered to become a preset shape by, for example, becoming a boundary of regions having mutually different surface states.

Also in this case, regarding the color 3D data 40 used as input data in the data processing unit 12, for example, it may be considered as input data, and the like in which a first color is applied to the coloring portion 142 serving as a first region on the surface of the three-dimensional shape indicated by the color 3D data 40 and a second color different from the first color is applied to the coloring portion 142 serving as a second region different from the first region on the surface. Also in this case, in the operation corresponding to step S104 in FIG. 3A, the data processing unit 12 detects, based on the color 3D data 40, for example, a first range that is a color range to which the first color is applied and a second range that is a color range to which the second color is applied. Also in this case, in the operations corresponding to step S106 and step S108 in FIG. 3A, the data processing unit 12, for example, generates molded object specification data by changing the shape of parts corresponding to the first range and the second range on the surface of the three-dimensional shape indicated by the color 3D data 40, setting the surface state in the first range to a first state, and setting the surface state in the second range to a second state different from the first state. In this case, regarding the state of parts corresponding to the first range and the second range on the surface of the three-dimensional shape indicated by the color 3D data 40, it may be considered that they are, for example, in the same state. Then, the data processing unit 12 applies mutually different shape changes to regions corresponding to the first range and the second range in the three-dimensional shape indicated by the color 3D data 40, thereby making the surface state of the first range and the surface state of the second range different in the molded object specification data. In the case of such a configuration as well, molded object specification data indicating a molded object 50 in which the boundary part 154 where a plurality of regions 152 colored with mutually different colors contact each other has a preset shape may be appropriately generated. Further, by this means, for example, a molded object 50 in which the boundary part 154 of the region 152 to be colored is easily identified may be appropriately modeled. Also, in this case, regarding the surface state of each region (region 152) in the molded object 50 corresponding to the first range and the second range, and the like described above, it is conceivable to set them to a state in which mutually different textured patterns are applied. The textured pattern may be considered as, for example, an uneven pattern in which a plurality of convex portions and a plurality of concave portions are formed. Also, in this case, by changing the size and arrangement of the convex portions and concave portions, the surface state of each region 152 may be appropriately differentiated.

Further, regarding the example shown in FIG. 4B, for example, this may be considered as an example in which the pattern for each region 152 is made to differ depending on the color to be applied, and the same pattern is added to the entire region 152 where coloring with the same color is performed. In contrast, in a further modification example of the operation of the data processing unit 12, as shown in FIG. 4C, for example, the surface state of only a part near the boundary part 154 in the region 152 may be changed. FIG. 4C shows an example of a state near the boundary part 154 in a further modification example of an operation of the data processing unit 12. In this case, in the operations corresponding to step S106 and step S108 in FIG. 3A, the data processing unit 12 generates, for example, molded object specification data indicating a shape in which textured unevennesses are added to at least a part of the range along the boundary part 154 with respect to the three-dimensional shape indicated by the color 3D data 40. Even when configured in this manner, for example, a molded object 50 in which the boundary part 154 of the region 152 to be colored is easily identified may be appropriately modeled. Further, in a further modification example of the operation of the data processing unit 12, it is also conceivable to generate, for example, molded object specification data indicating a shape in which textured unevennesses are added to only one side of the range along the boundary part 154 with respect to the three-dimensional shape indicated by the color 3D data 40. In this case, for example, textured unevennesses are added to only a part of the region 152 on one side with respect to the boundary part 154 among the two regions 152 shown in FIG. 4C. Even when configured in this manner, for example, the position of the boundary part 154 in the molded object 50 may be appropriately identified.

Next, supplementary descriptions and the like regarding each configuration described above will be provided. In the following, for the sake of convenience, the modification examples and the like described above may also be referred to as the present example. As also described above, in the present example, the modeling system 10 includes the data processing unit 12 and the modeling execution unit 14. In this case, the modeling system 10 may be, for example, a single apparatus including configurations corresponding to the data processing unit 12 and the modeling execution unit 14. Such a modeling system 10 may be considered as, for example, a configuration corresponding to a modeling apparatus. In this case, the data processing unit 12 may be considered as corresponding to, for example, a part that executes data processing in the modeling apparatus. Further, the modeling execution unit 14 may be considered as corresponding to, for example, a part that executes modeling in the modeling apparatus. Further, as the modeling system 10, it is also conceivable to use a configuration including, for example, a plurality of apparatuses corresponding to the data processing unit 12 and the modeling execution unit 14. In this case, as the data processing unit 12, for example, a computer or the like that executes data processing in the modeling system 10 may be suitably used. Further, in this case, the modeling execution unit 14 may be considered as having, for example, a configuration corresponding to a modeling apparatus.

Further, as also described above, in the case of forming a convex portion or a concave portion at the boundary part 154 of the region 152 in the molded object 50, the size of the convex portion or the concave portion may be appropriately changed according to, for example, the quality required for modeling. Further, in this case, it is conceivable that this convex portion or concave portion has a configuration that remains even after coloring is performed on the molded object 50. Thus, it is preferable to form this convex portion or concave portion with a size (height, depth, width, and the like) that becomes inconspicuous after coloring, for example. With this configuration, for example, it is possible to appropriately model the molded object 50 in which the boundary part 154 of the region 152 to be colored is easily identified while suppressing the influence on the quality of the molded object 50 after coloring.

Further, in this case, it is preferable to form a convex portion or a concave portion of a size that becomes inconspicuous by being filled with, for example, the paint used for coloring the molded object 50. More specifically, regarding the height of the convex portion or the depth of the concave portion, it is conceivable to set it to, for example, approximately 100 μm or less (for example, approximately 20 to 100 μm). Further, in the case of forming a convex portion at the boundary part 154, it is also conceivable to scrape off and remove the convex portion after coloring is performed. Further, in the case of forming a convex portion at the boundary part 154, it is also conceivable to make the height of the convex portion, for example, smaller than the thickness of the paint film formed on the surface of the molded object 50 when coloring the molded object 50. Further, in the case of forming a concave portion at the boundary part 154, it is also conceivable to set the depth of the concave portion to, for example, a depth that is appropriately filled with paint when coloring the molded object 50. Further, as shown in FIGS. 4B and 4C, in the case of adding a textured pattern to at least a part of the region 152 in the molded object 50, it is also preferable to form the unevenness in the textured pattern with, for example, a size that becomes inconspicuous after coloring.

### Industrial Applicability

The present invention may be suitably utilized in, for example, a modeling system, and the like

What is claimed is:

1. A modeling system for modeling a three-dimensional molded object, the modeling system comprising:
a data generation unit, configured to generate molded object specification data, which is data indicating a shape of the molded object; and
a modeling execution unit, configured to execute modeling of the molded object based on the molded object specification data,
wherein the data generation unit performs:
an input process of inputting, as input data, data indicating a three-dimensional shape in which at least a part of a surface is colored;
a color range detection process of detecting a color range, which is a range in which the color is applied in the input data; and
a data generation process of generating the molded object specification data in which a shape obtained by changing at least a part of a shape of a surface in the three-dimensional shape indicated by the input data becomes a shape of the molded object and generating the molded object specification data in which at least a boundary part in the color range detected in the color range detection process becomes a preset shape.

2. The modeling system according to claim 1, wherein in the data generation process, the data generation unit generates the molded object specification data indicating a shape in which a convex portion or a concave portion along the boundary part is added to the three-dimensional shape indicated by the input data.

3. The modeling system according to claim 1, wherein in the data generation process, the data generation unit generates the molded object specification data indicating a shape in which textured unevenness is added to at least a part of a range along the boundary part with respect to the three-dimensional shape indicated by the input data.

4. The modeling system according to claim 1, wherein the data generation unit:
inputs, in the input process, the input data in which a first color is applied to a first region on a surface and a second color different from the first color is applied to a second region on a surface different from the first region;
detects, in the color range detection process, a first range, which is the color range in which the first color is applied, and a second range, which is the color range in which the second color is applied; and
generates, in the data generation process, the molded object specification data in which, with respect to the three-dimensional shape indicated by the input data, a surface state in the first range is set to a first state and a surface state in the second range is set to a second state different from the first state.

5. The modeling system according to claim 2, wherein the data generation unit:
inputs, in the input process, the input data in which a first color is applied to a first region on a surface and a second color different from the first color is applied to a second region on a surface different from the first region;
detects, in the color range detection process, a first range, which is the color range in which the first color is applied, and a second range, which is the color range in which the second color is applied; and
generates, in the data generation process, the molded object specification data in which, with respect to the three-dimensional shape indicated by the input data, a surface state in the first range is set to a first state and a surface state in the second range is set to a second state different from the first state.

6. The modeling system according to claim 3, wherein the data generation unit:
inputs, in the input process, the input data in which a first color is applied to a first region on a surface and a second color different from the first color is applied to a second region on a surface different from the first region;
detects, in the color range detection process, a first range, which is the color range in which the first color is applied, and a second range, which is the color range in which the second color is applied; and
generates, in the data generation process, the molded object specification data in which, with respect to the three-dimensional shape indicated by the input data, a surface state in the first range is set to a first state and a surface state in the second range is set to a second state different from the first state.

7. The modeling system according to claim 1, wherein in the data generation process, the data generation unit performs: a deformed shape data generation process of generating deformed shape data, which is data indicating a shape obtained by changing a part of the three-dimensional shape indicated by the input data; and
a slice data generation process of generating slice data, which is data indicating a cross-section of the molded object, based on the deformed shape data,
wherein in the deformed shape data generation process, the data generation unit changes a part of the three-dimensional shape indicated by the input data so that at least the boundary part in the color range becomes a preset shape based on the color range detected in the color range detection process, and
the modeling execution unit models the molded object by stacking modeling material based on the slice data.

8. A data generation apparatus that generates molded object specification data, which is data indicating a three-dimensional molded object, wherein the data generation apparatus performs:
an input process of inputting, as input data, data indicating a three-dimensional shape in which at least a part of a surface is colored;
a color range detection process of detecting a color range, which is a range in which the color is applied in the input data; and
a data generation process of generating the molded object specification data in which a shape obtained by changing at least a part of a shape of a surface in the three-dimensional shape indicated by the input data becomes a shape of the molded object and generating the molded object specification data in which at least a boundary part in the color range detected in the color range detection process becomes a preset shape.

9. The data generation apparatus according to claim 8, wherein in the data generation process, a data generation unit generates the molded object specification data indicating a shape in which a convex portion or a concave portion along the boundary part is added to the three-dimensional shape indicated by the input data.

10. The data generation apparatus according to claim 8, wherein in the data generation process, a data generation unit generates the molded object specification data indicating a shape in which textured unevenness is added to at least a part of a range along the boundary part with respect to the three-dimensional shape indicated by the input data.

11. The data generation apparatus according to claim 8, wherein a data generation unit:
inputs, in the input process, the input data in which a first color is applied to a first region on a surface and a second color different from the first color is applied to a second region on a surface different from the first region;
detects, in the color range detection process, a first range, which is the color range in which the first color is applied, and a second range, which is the color range in which the second color is applied; and
generates, in the data generation process, the molded object specification data in which, with respect to the three-dimensional shape indicated by the input data, a surface state in the first range is set to a first state and a surface state in the second range is set to a second state different from the first state.

12. The data generation apparatus according to claim 9, wherein the data generation unit:
inputs, in the input process, the input data in which a first color is applied to a first region on a surface and a second color different from the first color is applied to a second region on a surface different from the first region;
detects, in the color range detection process, a first range, which is the color range in which the first color is applied, and a second range, which is the color range in which the second color is applied; and
generates, in the data generation process, the molded object specification data in which, with respect to the three-dimensional shape indicated by the input data, a surface state in the first range is set to a first state and a surface state in the second range is set to a second state different from the first state.

13. The data generation apparatus according to claim 10, wherein the data generation unit:
inputs, in the input process, the input data in which a first color is applied to a first region on a surface and a second color different from the first color is applied to a second region on a surface different from the first region;
detects, in the color range detection process, a first range, which is the color range in which the first color is applied, and a second range, which is the color range in which the second color is applied; and
generates, in the data generation process, the molded object specification data in which, with respect to the three-dimensional shape indicated by the input data, a surface state in the first range is set to a first state and a surface state in the second range is set to a second state different from the first state.

14. The modeling system according to claim 8, wherein in the data generation process, a data generation unit performs: a deformed shape data generation process of generating deformed shape data, which is data indicating a shape obtained by changing a part of the three-dimensional shape indicated by the input data; and
a slice data generation process of generating slice data, which is data indicating a cross-section of the molded object, based on the deformed shape data,
wherein in the deformed shape data generation process, the data generation unit changes a part of the three-dimensional shape indicated by the input data so that at least the boundary part in the color range becomes a preset shape based on the color range detected in the color range detection process, and
a modeling execution unit models the molded object by stacking modeling material based on the slice data.

15. A data generation method for generating molded object specification data, which is data indicating a three-dimensional molded object, the data generation method comprising:
an input stage of inputting, as input data, data indicating a three-dimensional shape in which at least a part of a surface is colored;
a color range detection stage of detecting a color range, which is a range in which the color is applied in the input data; and
a data generation stage of generating the molded object specification data in which a shape obtained by changing at least a part of a shape of a surface in the three-dimensional shape indicated by the input data becomes a shape of the molded object and generating the molded object specification data in which at least a boundary part in the color range detected in the color range detection stage becomes a preset shape.

16. The data generation method according to claim 15, wherein in the data generation stage, a data generation unit generates the molded object specification data indicating a shape in which a convex portion or a concave portion along the boundary part is added to the three-dimensional shape indicated by the input data.

17. The data generation method according to claim 15, wherein in the data generation stage, a data generation unit generates the molded object specification data indicating a shape in which textured unevenness is added to at least a part of a range along the boundary part with respect to the three-dimensional shape indicated by the input data.

18. The data generation method according to claim 15, wherein a data generation unit:
inputs, in the input stage, the input data in which a first color is applied to a first region on a surface and a second color different from the first color is applied to a second region on a surface different from the first region;
detects, in the color range detection stage, a first range, which is the color range in which the first color is applied, and a second range, which is the color range in which the second color is applied; and
generates, in the data generation stage, the molded object specification data in which, with respect to the three-dimensional shape indicated by the input data, a surface state in the first range is set to a first state and a surface state in the second range is set to a second state different from the first state.

19. The data generation method according to claim 16, wherein the data generation unit:
inputs, in the input stage, the input data in which a first color is applied to a first region on a surface and a second color different from the first color is applied to a second region on a surface different from the first region;
detects, in the color range detection stage, a first range, which is the color range in which the first color is applied, and a second range, which is the color range in which the second color is applied; and
generates, in the data generation stage, the molded object specification data in which, with respect to the three-dimensional shape indicated by the input data, a surface state in the first range is set to a first state and a surface state in the second range is set to a second state different from the first state.

20. The data generation method according to claim 15, wherein in the data generation stage, a data generation unit performs: a deformed shape data generation stage of generating deformed shape data, which is data indicating a shape obtained by changing a part of the three-dimensional shape indicated by the input data; and
a slice data generation stage of generating slice data, which is data indicating a cross-section of the molded object, based on the deformed shape data,
wherein in the deformed shape data generation stage, the data generation unit changes a part of the three-dimensional shape indicated by the input data so that at least the boundary part in the color range becomes a preset shape based on the color range detected in the color range detection stage, and
a modeling execution unit models the molded object by stacking modeling material based on the slice data.
